(19) United States
(12) Patent Application Publication
(10) Pub. No.: US 2013/0181585 A1
(43) Pub. Date: Jul. 18, 2013

(54) ENCLOSED CONTROL HEAT-REGULATION DEVICE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: XIN ZHU, Shenzhen (CN); CHUN-TIAN FAN, Shenzhen (CN); WEI-HUA LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/730,804

(22) Filed: Dec. 28, 2012

(30) Foreign Application Priority Data
Jan. 13, 2012 (CN) 201210010347.5

(51) Int. Cl. H05K 7/20

(52) U.S. Cl. CPC H05K 7/20
USPC 312/236; 165/104.13

(57) ABSTRACT

An enclosed control device for heat regulation includes a housing and a heat dissipation mechanism. The heat dissipation mechanism includes at least one heat dissipation member mounted on the housing and a heat dissipation fan mounted in the housing. A cooling runner is defined in the at least one heat dissipation member. An inlet and an outlet are defined in the at least one heat dissipation member. The inlet and the outlet communicate with the cooling runner. The inlet is connected to a cooling liquid source to recycle cooling liquid in the cooling runner. The heat dissipation fan is placed opposite to the at least one heat dissipation member, such that air in the housing is also recycled and flowed into the at least one heat dissipation member.

### BACKGROUND

1. Technical Field

The present disclosure relates to control devices, and particularly to an enclosed control device capable of dissipating heat.

2. Description of Related Art

In a severe work environment, such as in a dusty or spraying environment, a usage life of a control device may be affected negatively. In addition, because dust or paint spray may enter inside of the control device, an explosion may easily occur. Therefore, the control device used in such work environment is usually enclosed, confined or sealed. In a working process, heat is generated by the control device, such that a heat dissipation device is required to be mounted on the control device to dissipate the heat, such as a liquid cooling heat dissipation device. The liquid cooling heat dissipation device includes a heat dissipation member, a sealing plate, and a sealing washer. A cooling groove is defined in the heat dissipation member. The sealing plate is mounted on the heat dissipation member. The sealing washer is placed between the sealing plate and the heat dissipation member to seal the cooling groove, thereby forming a cooling runner. However, because the heat dissipation device includes a plurality of separate components, the potential for leakages of the cooling liquid in the cooling runner is high, and the heat dissipation device is complicated to assemble and disassemble.

Therefore, there is room for improvement in the art.

### BRIEF DESCRIPTION OF THE DRAWINGS

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is an assembled, isometric view of an embodiment of an enclosed control device.

FIG. 2 is an exploded, isometric view of the enclosed control device of FIG. 1.

FIG. 3 is a partial, exploded, isometric view of the enclosed control device of FIG. 1.

FIG. 4 is a partial, assembled, isometric view of the enclosed control device of FIG. 3.

FIG. 5 is a sectional view of the enclosed control device of FIG. 3, taken along line V-V of FIG. 4.

### DETAILED DESCRIPTION

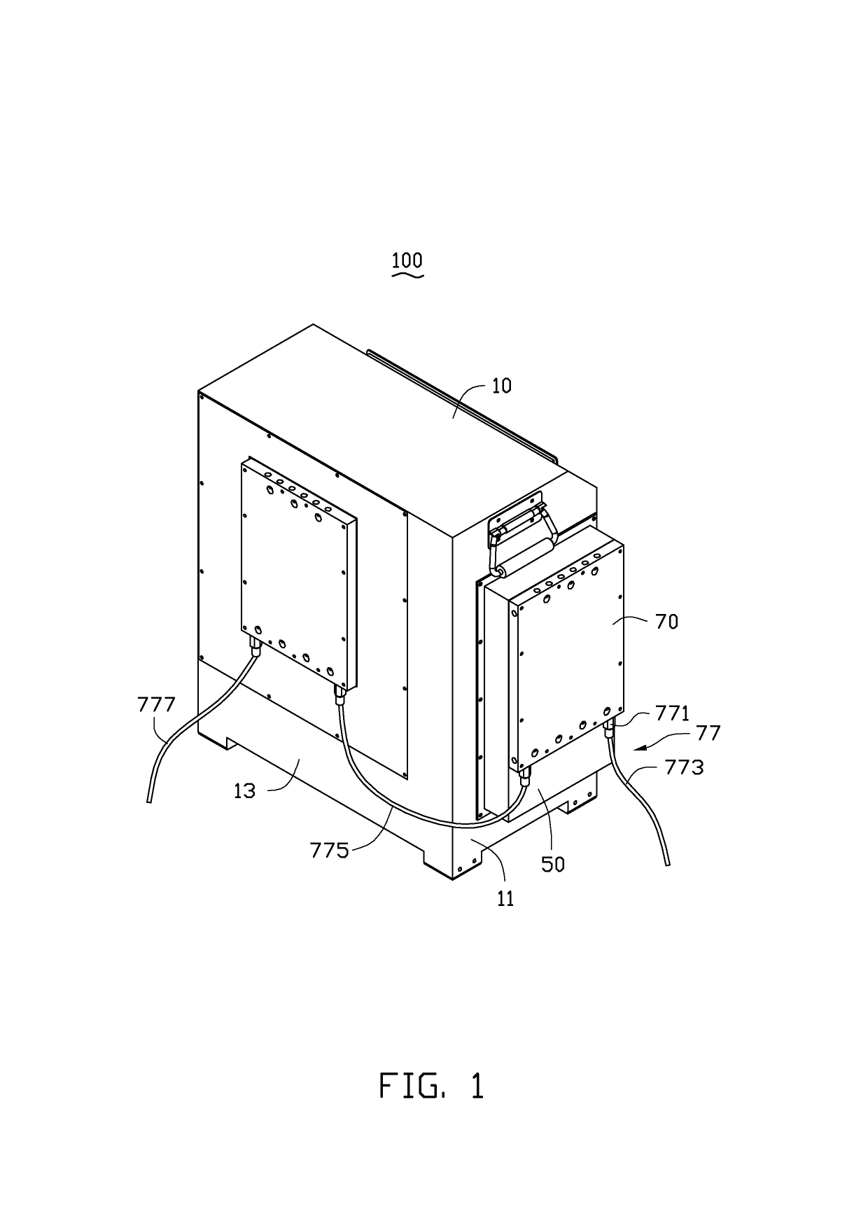

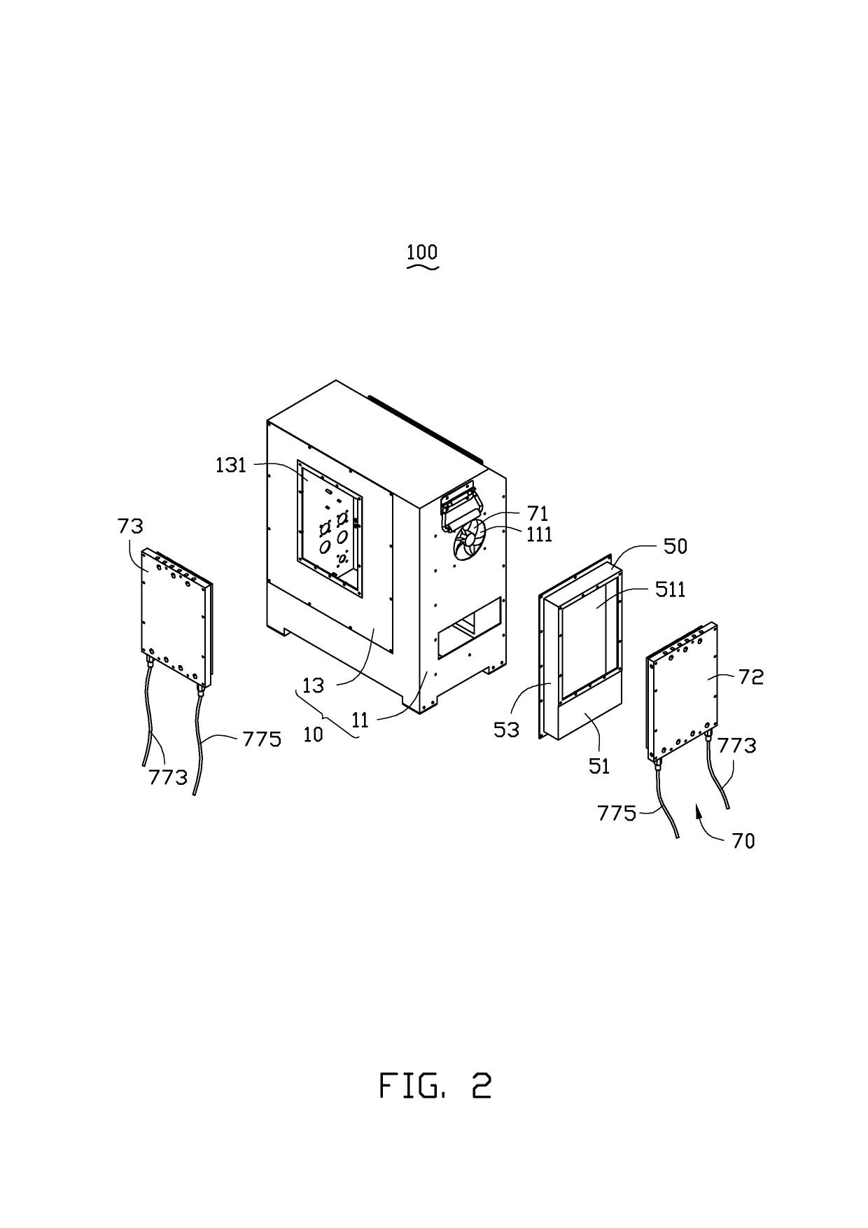

FIGS. 1 and 2 show an embodiment of an enclosed control device 100. The enclosed control device 100 includes a housing 10, a cover 50, and a heat dissipation mechanism 70. The cover 50 is mounted on an outer surface of the housing 10. The heat dissipation mechanism 70 is mounted on the housing 10 and the cover 50, for cooling the enclosed control device 100. The enclosed control device 100 further includes other functional modules, such as a central processing unit (not shown) and a control module (not shown). However, for simplicity, only the housing 10, the cover 50, and the heat dissipation mechanism 70 are described in detail. In the illustrated embodiment, the enclosed control device 100 is a control device for a robot.

The housing 10 is hollow and substantially rectangular. The housing 10 includes a first side surface 11 and a second side surface 13 connected to the first side surface 11. A fan hole 111, which is a through hole, is defined in the first side surface 11. The fan hole 111 is substantially circular. A mounting hole 131, which is another through hole, is defined in the second side surface 13 of the housing 10. The mounting hole 131 is substantially rectangular.

The cover 50 is substantially a frame. The cover 50 includes a top surface 51 and a peripheral surface 53 connected to edges of the top surface 51. The top surface 51 and the peripheral surface 53 cooperatively define an opening (not shown). The peripheral surface 53 is mounted on the first side surface 11, such that the opening of the cover 50 communicates with the fan hole 111. A receiving hole 511 is defined in the top surface 51, for partially receiving the heat dissipation mechanism 70.

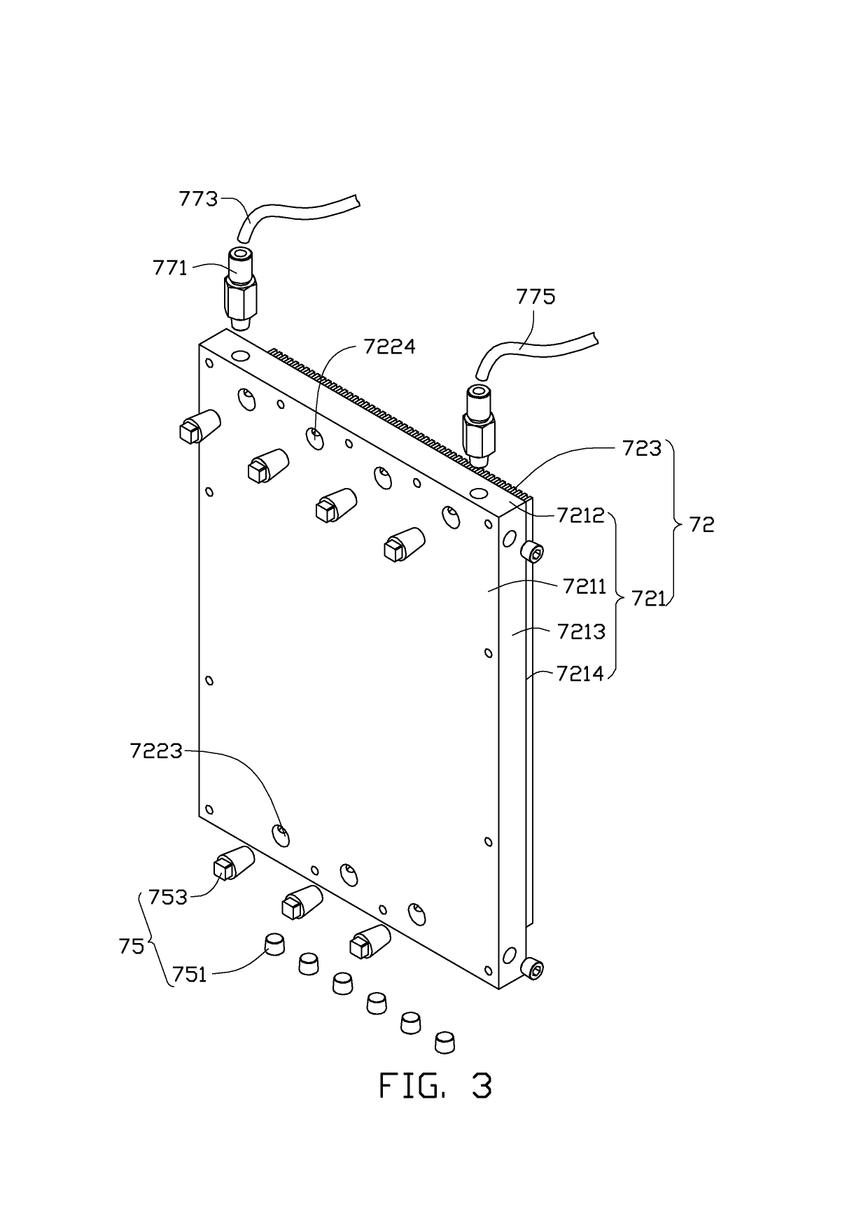

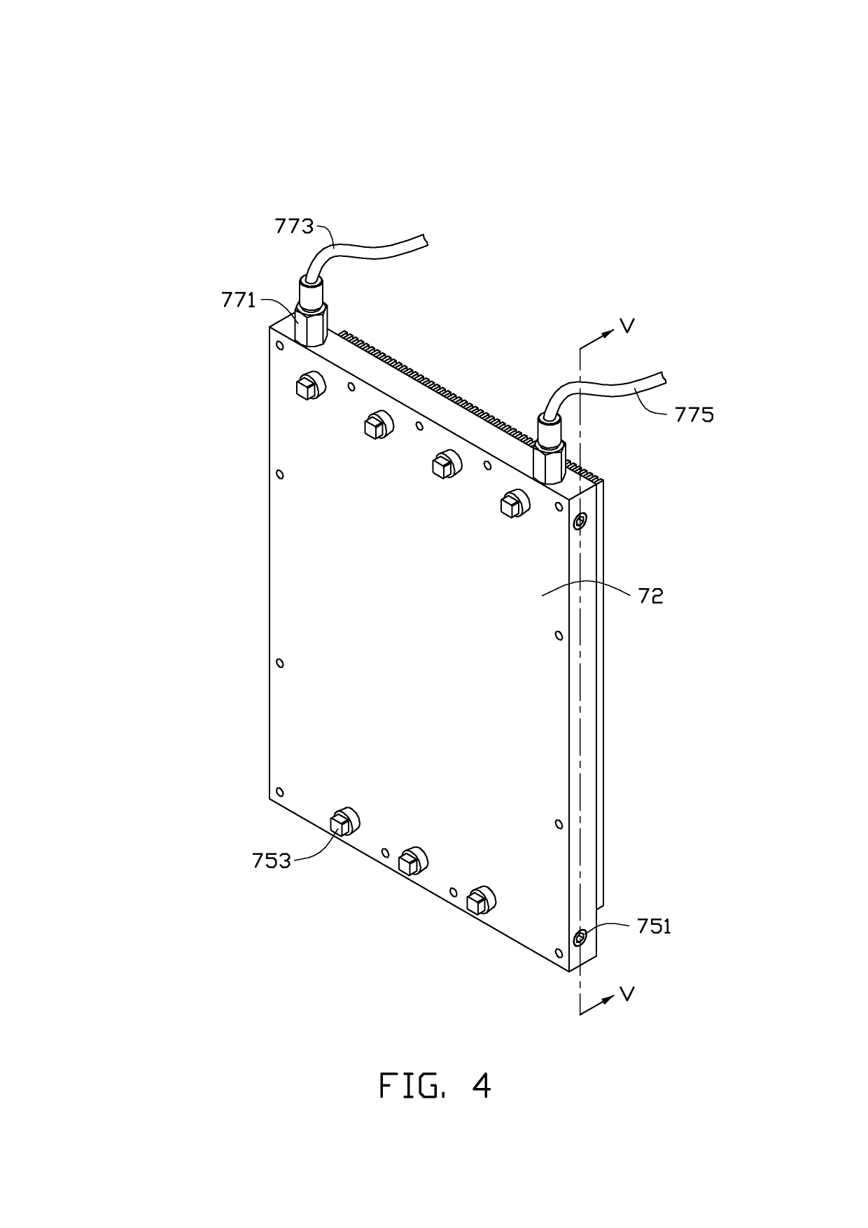

Referring also to FIGS. 3 through 5, the heat dissipation mechanism 70 includes a heat dissipation fan 71, a first heat dissipation member 72, a second heat dissipation member 73, a plurality of sealing assemblies 75, and a hose assembly 77. The heat dissipation fan 71 is mounted in the housing 10, and opposite to the fan hole 111. The first heat dissipation member 72 is mounted on the cover 50, and covers the receiving hole 511. When the heat dissipation fan 71 is running or under operation, the air inside the housing 10 is recycled, and flows to the first heat dissipation member 72 through the fan hole 111, the opening of the cover 50, and the receiving hole 511. The second heat dissipation member 73 is mounted on the second side surface 13, and covers the mounting hole 131. The sealing assemblies 75 and the hose assembly 77 are mounted on the first and second heat dissipation members 72, 73.

The first heat dissipation member 72 includes a main body 721 and a plurality of heat dissipation fins 723 mounted on the main body 721. The main body 721 is substantially rectangular and plate-like, and includes a top wall 7211, two opposite first sidewalls 7212, two opposite second sidewalls 7213, and a bottom wall 7214. The first sidewalls 7212 and the second sidewalls 7213 extend from a periphery of the top wall 7211, and interconnect the top wall 7211 and the bottom wall 7214.

Two first channels 7215 and six second runners 7218 are defined between the two first sidewalls 7212. The first channels 7215 are parallel to the second runners 7218. The two first channels 7215 are adjacent to the two second sidewalls 7213. Two gates of the two first channels 7215 are defined in one of the two first sidewalls 7212, in which one gate is defined as an inlet 7216, and the other gate is defined as an outlet 7217. The six second runners 7218 are uniformly defined between the two first channels 7215. Gates of the six second runners 7218 are defined in the other one of the two first sidewalls 7212. A third runner 7219 is defined in one end of one second sidewall 7213 towards the other second sidewall 7213. A fourth runner 7220 is defined in the other end of the one second sidewall 7213 towards the other second sidewall 7213. The third runner 7219 and the fourth runner 7220 communicate with the first channels 7215 and the second runners 7218. The third runner 7219 is divided into a plurality of first communication sections 7221. The fourth runner 7220 is divided into a plurality of second communication sections 7222.

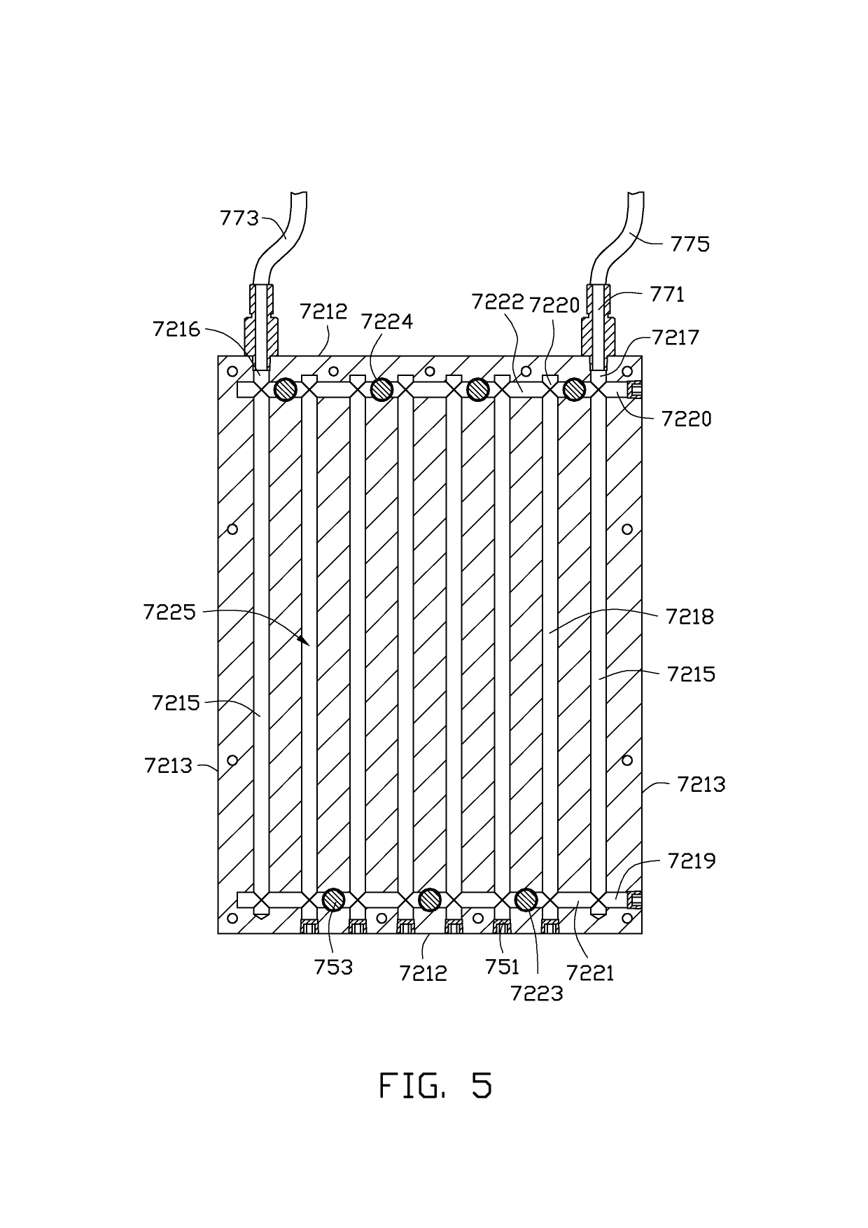

A plurality of first sealing holes 7223 and a plurality of second sealing holes 7224 are defined in the top wall 7211. Each first sealing hole 7223 is defined in a substantially middle portion of one first communication section 7221, and one first communication section 7221 is between two first sealing holes 7223. Each second sealing hole 7224 is defined in a substantially middle portion of one second communication section 7222, and one second communication section 7222 is between two second sealing holes 7224. The first sealing holes 7223 and the second sealing holes 7224 are alternately located at the top and the bottom of the top wall 7211, in a zigzag pattern (see FIG. 5).

The heat dissipation fins 723 pass through the receiving hole 511, and are received in the cover 50 opposite to the heat dissipation fan 71. The heat dissipation fins 723 are substantially rectangular and plate-like, and extend from the bottom wall 7214 away from the main body 721. The heat generated in the housing 10 is conducted to the main body 721 by the heat dissipation fan 71 and the heat dissipation fins 723.

The second heat dissipation member 73 is mounted on the second side surface 13 opposite to the mounting hole 131. The heat dissipation fins 723 pass through the mounting hole 131 and are received in the housing 10. The second heat dissipation member 73 has substantially the same structure as the first heat dissipation member 72.

Each sealing assembly 75 includes a sealing member 751 and a plug 753. A plurality of sealing members 751 of the sealing assemblies 75 are securely mounted in the gates of the second runner 7218, the third runner 7219, and the fourth runner 7220, for preventing leakage of the cooling liquid from the gates. A plurality of plugs 753 of the sealing assemblies 75 are securely mounted in the first sealing holes 7223 and the second sealing holes 7224. Thus, the first channels 7215, the second runners 7218, the third runners 7219, and the fourth runners 7220 cooperatively form a rectangular and sinusoidal cooling runner 7225.

The hose assembly 77 includes four valves 771, a first hose 773, a second hose 775, and a third hose 777. The valves 771 are mounted in the inlet 7216 and the outlet 7217 of the first heat dissipation member 72, in an inlet (not labeled) and an outlet (not labeled) of the second heat dissipation member 73. One end of the first hose 773 is connected with the valve 771 mounted in the inlet 7216, and the other end of the first hose 773 is connected to a cooling liquid source (not shown). One end of the second hose 775 is connected to the valve 771 mounted in the outlet 7217, and the other end of the second 775 is connected to the valve 771 mounted in the inlet of the second heat dissipation member 73. One end of the third hose 777 is connected to the valve 771 mounted in the outlet of the second heat dissipation member 73, and the other end of the third hose 777 is connected to a cooling liquid receiving member (not shown).

In use, the cooling liquid enters into the cooling runner 7225 through the first hose 773 connected to the cooling liquid source. Upon starting the heat dissipation fan 71, the air in the enclosed control device 100 is forced onto the heat dissipation fins 723 of the first heat dissipation member 72 by the heat dissipation fan 71, and the heat of the air is thus conducted to the main body 721. The cooling liquid in the cooling runner 7225 absorbs the heat, and the air is cooled down. The cooled air is forced into the housing 10 by the heat dissipation fan 71. The cooling liquid absorbs the heat flowing into the second hose 775 by virtue of a cooling runner of the second heat dissipation member 73. The heat is then conducted to a main body of the second heat dissipation member 73, the cooling liquid absorbs the heat and then flows into the cooling liquid receiving member through the third hose 777. Thus, there is a very rapid dissipation of heat by the enclosed control device 100.

The heat dissipation fan 71 recycles the air in the housing 10, and the heat is conducted to the first and second heat dissipation members 72, 73, so that the heat is rapidly and effectively dissipated. In addition, the cooling runner 7225 is directly formed in the first heat dissipation member 72, and another cooling runner is directly formed in the second heat dissipation member 73, so that a great plurality of separate components is avoided. Therefore, the assembly process of the first and second heat dissipation members 72, 73 is quicker and simpler, and the cooling liquid is far less likely to leak out.

In other embodiments, the cover 50 can be omitted, and the first heat dissipation member 72 is directly mounted on the first side surface 11. A number of the heat dissipation fans 71 can be changed as needed, such as two or more. The sealing assemblies 75 can be omitted, and the cooling runner 7225 can be directly defined in the first heat dissipation member 72. The hose assembly 77 can be omitted, the inlet 7216 can be directly connected to the cooling liquid source, and the outlet of the second heat dissipation member 73 can be directly connected to the cooling liquid receiving member. A number of the heat dissipation members can be changed as needed. A number of the first channels 7215 can be changed as needed.

While various embodiments have been described and illustrated, the disclosure is not to be construed as being restricted thereto. Various modifications can be made to the embodiments by those skilled in the art without departing from the true spirit and scope of the disclosure as defined by the appended claims.

What is claimed is:

1. An enclosed control device, comprising:
a housing; and
a heat dissipation mechanism comprising at least one heat dissipation member mounted on the housing and a heat dissipation fan mounted in the housing, wherein a cooling runner is defined in the at least one dissipation member, an inlet and an outlet are defined in the at least one dissipation member, the inlet and the outlet are communicated with the cooling runner, the inlet is constructed for being connected to a cooling liquid source to recycle a cooling liquid in the cooling runner, and the heat dissipation fan is placed opposite to one of the at least one heat dissipation member, such that air in the housing is recycled and flows toward the at least one heat dissipation member.

2. The enclosed control device of claim 1, wherein each of the at least one heat dissipation member comprises a main body and a plurality of heat dissipation fins mounted on the main body, the cooling runner is defined in the main body.

3. The enclosed control device of claim 1, wherein the housing comprises a first side surface, a fan hole is defined in the first side surface of the housing, and the heat dissipation fan is opposite to the fan hole.

4. The enclosed control device of claim 3, wherein the enclosed control device further comprises a cover mounted on the first side surface of the housing and opposite to the fan hole, the one of the at least one heat dissipation member is mounted on the housing via the cover.

5. The enclosed control device of claim 4, wherein the one of the at least one heat dissipation member comprises a main body and a plurality of heat dissipation fins mounted on the main body, and the heat dissipation fins of the one of the at least one heat dissipation member are received in the cover.

6. The enclosed control device of claim 1, wherein the at least one heat dissipation member comprises a first heat dissipation member and a second heat dissipation member, the first heat dissipation member is placed opposite to the heat dissipation fan.

7. The enclosed control device of claim 6, wherein the cooling runner in the first heat dissipation member is communicated with the cooling runner in the second heat dissipation member.

8. The enclosed control device of claim 6, wherein the housing comprises a first side surface and a second side surface connected to the first side surface, the first heat dissipation member is mounted on the first side surface, and the second heat dissipation member is mounted on the second side surface.

9. The enclosed control device of claim 8, wherein a fan hole is defined in the first side surface, and the heat dissipation fan is opposite to the fan hole.

10. The enclosed control device of claim 8, wherein a mounting hole is defined in the second side surface, the second heat dissipation member is opposite to the mounting hole.

11. The enclosed control device of claim 10, wherein the second heat dissipation member comprises a main body mounted on the second side surface and a plurality of heat dissipation fins, and the plurality of the heat dissipation fins pass through the mounting hole and are received in the housing.

12. The enclosed control device of claim 7, wherein the heat dissipation mechanism further comprises a hose assembly, and the cooling runner in the first heat dissipation member is communicated with the cooling runner in the second heat dissipation member via the hose assembly.

13. The enclosed control device of claim 1, wherein the cooling runner is sinusoidal.

14. The enclosed control device of claim 1, wherein the heat dissipation mechanism further a plurality of sealing assemblies mounted on the at least one heat dissipation member for preventing the cooling liquid leaking out.
